(19) United States
(12) Patent Application Publication
(10) Pub. No.: US 2025/0096737 A1
(43) Pub. Date: Mar. 20, 2025

(54) LOW-NOISE AMPLIFIER (LNA) INPUT IMPEDANCE IMPROVEMENT USING COUPLING BETWEEN OUTPUT INDUCTOR AND DEGENERATION INDUCTOR

(71) Applicant: QUALCOMM Incorporated, San Diego, CA (US)

(72) Inventors: Xingyi HUA, San Diego, CA (US); Hsiao-Tsung YEN, San Diego, CA (US); David Zixiang YANG, San Diego, CA (US); Mehmet UZUNKOL, San Diego, CA (US)

(21) Appl. No.: 18/470,310

(22) Filed: Sep. 19, 2023

(51) Int. Cl. H03F 1/26; H03H 7/01; H03H 7/06; H03H 7/09; H04B 1/40

(52) U.S. Cl. CPC H03F 1/26; H03H 7/0176; H03H 7/06; H03H 7/09; H04B 1/40; H03F 2200/301; H03F 2200/372; H03F 2200/489; H03F 2203/21

(57) ABSTRACT

A low-noise amplifier (LNA) includes a first transistor, a first source inductor coupled to a source of the first transistor, and a second transistor, wherein a source of the second transistor is coupled to a drain of the first transistor, a gate of the second transistor is coupled to a bias circuit, and a drain of the second transistor is coupled to an output of the LNA. The LNA also includes an output inductor coupled between a supply rail and the output of the LNA, wherein the output inductor is magnetically coupled with the first source inductor.

### FIELD

Aspects of the present disclosure relate generally to wireless communications, and, more particularly, to low-noise amplifiers.

### BACKGROUND

A wireless device (e.g., smart phone) may transmit and receive radio frequency (RF) signals in one or more wireless networks (e.g., long-term evolution (LTE) network, fifth generation (5G) network, wireless local area network (WLAN), etc.). To receive RF signals, the wireless device includes one or more antennas and one or more low-noise amplifiers (LNAs) configured to amplify RF signals received by the one or more antennas.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a system for wireless communications. The system includes a low-noise amplifier (LNA). The LNA includes a first transistor, a first source inductor coupled to a source of the first transistor, and a second transistor, wherein a source of the second transistor is coupled to a drain of the first transistor, a gate of the second transistor is coupled to a bias circuit, and a drain of the second transistor is coupled to an output of the LNA. The LNA also includes an output inductor coupled between a supply rail and the output of the LNA, wherein the output inductor is magnetically coupled with the first source inductor.

A second aspect relates to a system for wireless communications. The system includes a radio frequency front-end (RFFE) circuit coupled to one or more antennas and including a low-noise amplifier (LNA). The LNA includes a first transistor, a first source inductor coupled to a source of the first transistor, and a second transistor, wherein a source of the second transistor is coupled to a drain of the first transistor, a gate of the second transistor is coupled to a bias circuit, and a drain of the second transistor is coupled to an output of the LNA. The LNA also includes an output inductor coupled between a supply rail and the output of the LNA, wherein the output inductor is magnetically coupled with the first source inductor. The system also includes a receiver coupled to the output of the LNA.

A third aspect relates to a method for operating a wireless communications system including a low-noise amplifier (LNA), the LNA comprising a first transistor, a first source inductor coupled to a source of the first transistor, a second transistor coupled between an output of the LNA and a drain of the first transistor, and an output inductor coupled between a supply rail and the output of the LNA. The method includes biasing a gate of the second transistor with a bias voltage, receiving a first radio frequency (RF) signal in a first frequency band, inputting the first RF signal to a gate of the first transistor; and magnetically coupling the first source inductor with the output inductor.

A fourth aspect relates to a low-noise amplifier (LNA). The LNA includes a first transistor, a first source inductor coupled to a source of the first transistor, and a second transistor, wherein a source of the second transistor is coupled to a drain of the first transistor, a gate of the second transistor is coupled to a bias circuit, and a drain of the second transistor is coupled to an output of the LNA. The LNA also includes an output inductor coupled between a supply rail and the output of the LNA, wherein the output inductor is magnetically coupled with the first source inductor.

### BRIEF DESCRIPTION OF THE DRAWINGS

FIG. 1 shows an example of a receiver including a filter and a low-noise amplifier (LNA) according to certain aspects of the present disclosure.

FIG. 2 shows an example in which the filter and the LNA are included on an RF front-end circuit coupled to an antenna according to certain aspects of the present disclosure.

FIG. 3 shows an exemplary implementation of an LNA according to certain aspects of the present disclosure.

FIG. 4 shows an example of an LNA including an output inductor and a source inductor in which the source inductor is magnetically coupled with the output inductor according to certain aspects of the present disclosure.

FIG. 5A shows an exemplary layout of the output inductor and the source inductor of FIG. 4 in which the output inductor is arranged next to the source inductor according to certain aspects of the present disclosure.

FIG. 5B shows an exemplary layout of the output inductor and the source inductor of FIG. 4 in which the output inductor and the source inductor partially overlap according to certain aspects of the present disclosure.

FIG. 6 shows another exemplary layout of the output inductor and the source inductor of FIG. 4 according to certain aspects of the present disclosure.

FIG. 7 shows an example of an LNA including an output inductor, a first source inductor, and a second source inductor in which the first source inductor and the second source inductor are magnetically coupled with the output inductor according to certain aspects of the present disclosure.

FIG. 8A shows an exemplary layout of the output inductor, the first source inductor, and the second source inductor of FIG. 7 in which output inductor is arranged next to the first source inductor and next to the second source inductor according to certain aspects of the present disclosure.

FIG. 8B shows an exemplary layout of the output inductor, the first source inductor, and the second source inductor of FIG. 7 in which the first source inductor partially overlaps the output inductor and the second source inductor partially overlaps the output inductor according to certain aspects of the present disclosure.

FIG. 9 shows another exemplary layout of the output inductor, the first source inductor, and the second source inductor of FIG. 7 according to certain aspects of the present disclosure.

FIG. 10 shows an example of a first filter coupled to a first input of the LNA of FIG. 7 and a second filter coupled to a second input of the LNA of FIG. 7 according to certain aspects of the present disclosure.

FIG. 11 shows an example in which the first filter and the second filter of FIG. 10 are coupled to a common antenna according to certain aspects of the present disclosure.

FIG. 12 shows an example in which the first filter of FIG. 10 is coupled to a first antenna and the second filter of FIG. 10 is coupled to a second antenna according to certain aspects of the present disclosure.

FIG. 13 shows an example in which an output of the LNA of FIG. 7 is coupled to a mixer according to certain aspects of the present disclosure.

FIG. 14 shows an example in which an output of the LNA of FIG. 7 is coupled to a first mixer and a second mixer according to certain aspects of the present disclosure.

FIG. 15 is a diagram of an environment including an electronic device that includes a transceiver according to certain aspects of the present disclosure.

FIG. 16 is a flowchart illustrating a method for operating a wireless communications system according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

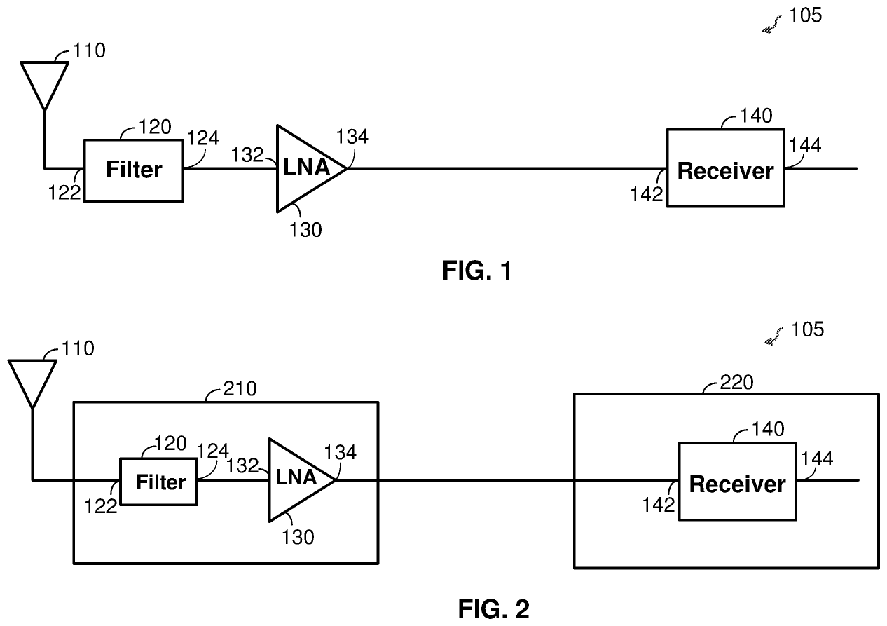

A receiver of a wireless device may include one or more low-noise amplifiers (LNAs) configured to amplify radio frequency (RF) signals received by one or more antennas. In this regard, FIG. 1 shows an example of a system 105 including an LNA 130 according to certain aspects. In this example, the system 105 also includes an antenna 110, a filter 120 (also referred to as a filter circuit), and a receiver 140 (also referred to as a receive chain). The receiver 140 may be included in a transceiver. The system 105 may be incorporated in a wireless device (e.g., a mobile wireless device, an access point, etc.). Although one antenna 110, one filter 120, and one LNA 130 are shown in FIG. 1, it is to be appreciated that the wireless device may include multiple antennas (e.g., arranged in an array), multiple filters, and/or multiple LNAs.

In the example in FIG. 1, the filter 120 has an input 122 coupled to the antenna 110, and an output 124. The LNA 130 has an input 132 coupled to the output 124 of the filter 120, and an output 134. The receiver 140 has an input 142 coupled to the output 134 of the LNA 130, and an output 144. The output 144 of the receiver 140 may be coupled to a baseband processor (also referred to as a modem), an intermediate frequency (IF) circuit, or another type of circuit.

In one example, the filter 120 is a bandpass filter configured to pass an RF signal received from the antenna 110 within a desired frequency band (i.e., pass band) while filtering out signals (e.g., interfering signals) outside the desired frequency band. The LNA 130 is configured to receive the RF signal at the input 132, amplify the RF signal, and output the amplified RF signal at the output 134.

The receiver 140 is configured to receive the RF signal at the input 142, convert the RF signal into a baseband signal or an intermediate frequency (IF) signal, and output the baseband signal or the IF signal at the output 144. For example, the receiver 140 may include a mixer (not shown) configured to mix the RF signal with a local oscillator signal to frequency downconvert the RF signal to obtain the baseband signal or the IF signal. The receiver 140 may also include one or more amplifiers (e.g., such as one or more additional LNAs), one or more filters, a phase shifter, or any combination thereof.

For the example where the receiver 140 outputs a baseband signal, the output 144 may be coupled to a baseband processor (not shown). In this example, the baseband processor may decode and/or demodulate the baseband signal to recover data and/or control information from the baseband signal.

For the example where the receiver 140 outputs an IF signal, the output 144 may be coupled to an IF circuit (not shown). In this example, the IF circuit may frequency downconvert the IF signal to obtain a baseband signal and output the baseband signal to a baseband processor.

FIG. 2 shows an example in which the filter 120 and the LNA 130 are included on an RF front-end circuit 210 located close to the antenna 110 to reduce signal losses between the antenna 110 and the RF front-end circuit 210. In this example, the receiver 140 is integrated on a chip 220 coupled to the RF front-end circuit 210 via one or more metal traces, a transmission line, a cable, etc. In this example, the receiver 140 may also be referred to as a receiver integrated circuit since the receiver 140 is integrated on the chip 220 is this example. In one example, the RF front-end circuit 210 and the chip 220 may be mounted on a substrate (e.g., a printed circuit board (PCB)). The filter 120 and the LNA 130 may be integrated on the same chip or may be integrated on separate chips. In some implementations, the LNA 130 and the receiver 140 may be integrated on the same chip (i.e., die).

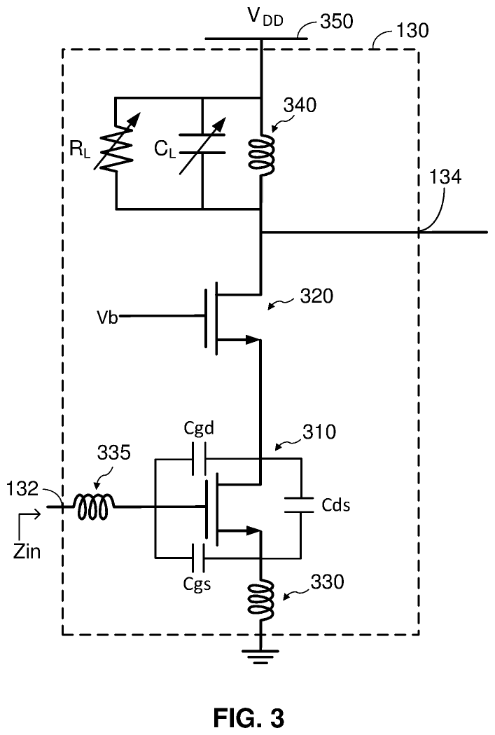

FIG. 3 shows an exemplary implementation of the LNA 130 according to certain aspects. In this example, the LNA 130 includes a first transistor 310, a second transistor 320, a source inductor 330 (also referred to as a source degeneration inductor), a gate inductor 335, and an output inductor 340 (also referred to as a load inductor). In the example in FIG. 3, the first transistor 310 is implemented with a first n-type field effect transistor (NFET) and the second transistor 320 is implemented with a second NFET. However, it is to be appreciated that the present disclosure is not limited to this example, and that the transistors 310 and 320 may be implemented with other types of transistors.

The source inductor 330 is coupled between the source of the first transistor 310 and a ground (or some reference potential), and the gate inductor 335 is coupled between the gate of the first transistor 310 and the input 132 of the LNA 130. In this example, the source inductor 330 provides the first transistor 310 with source degeneration (e.g., to improve the linearity of the LNA 130). The gate inductor 335 may be used for input impedance matching.

The source of the second transistor 320 is coupled to the drain of the first transistor 310, the gate of the second transistor 320 is biased by a bias voltage Vb, and the drain of the second transistor 320 is coupled to the output 134 of the LNA 130. The output inductor 340 is coupled between the output 134 of the LNA 130 and a supply rail 350. The supply rail 350 is configured to provide a supply voltage V_{DD}.

In this example, the first transistor 310 and the second transistor 320 are arranged in a cascode configuration with the first transistor 310 functioning as a common-source amplifier and the second transistor 320 functioning as a common-gate amplifier.

The LNA 130 may also include a tunable load capacitor C_{L} and a tunable load resistor R_{L} coupled in parallel with the output inductor 340. The tunable load capacitor C_{L} and the tunable load resistor R_{L} may be used to provide frequency selection and/or gain selection by tuning the capacitance of the load capacitor C_{L} and/or tuning the resistance of the load resistor R_{L}. The tunable load capacitor C_{L} and/or the tunable load resistor R_{L} may be omitted in some implementations.

FIG. 3 shows an example of the drain-to-source capacitance Cds, the gate-to-drain capacitance Cgd, and the gate-to-source capacitance Cgs of the first transistor 310. Although these capacitances are depicted as capacitors coupled to the first transistor 310 in FIG. 1 for purposes of illustration, it is to be appreciated that these capacitances are due to the structure of the first transistor 310, and are therefore inherent in the first transistor 310.

A challenge with the LNA 130 is that the real part of the input impedance Re(Zin) and the real part of the optimum impedance Re(Zopt) may be far apart from each other (e.g., Re(Zin)=40Ω and Re(Zopt)=98Ω), where the optimum impedance is an impedance that minimizes a noise figure (NF) of the LNA 130. The large separation between the real part of the input impedance Re(Zin) and the real part of the optimum impedance Re(Zopt) makes it difficult for the LNA 130 to achieve both low NF and low return loss.

The gate-to-drain capacitance Cgd of the first transistor 310 reduces Zin while having no impact on Zopt. As a result, the gate-to-drain capacitance Cgd makes it more difficult to bring the real part of the input impedance Re(Zin) and the real part of the optimum impedance Re(Zopt) closer together to achieve both low NF and low return loss for the LNA 130.

To address the above, aspects of the present disclosure provide magnetic coupling between the output inductor and the source inductor of an LNA. The magnetic coupling (also referred to as inductive coupling) helps bring the real part of the input impedance Re(Zin) and the real part of the optimum impedance Re(Zopt) closer together for low NF and low return loss. The magnetic coupling also increases the effective gate-to-source capacitance Cgs of the first transistor (also referred to as the input transistor), which allows input impedance matching using a smaller gate inductor. The smaller gate inductor reduces losses in the gate inductor, which also helps lower the NF of the LNA. The above features and other features of the present disclosure are discussed further below.

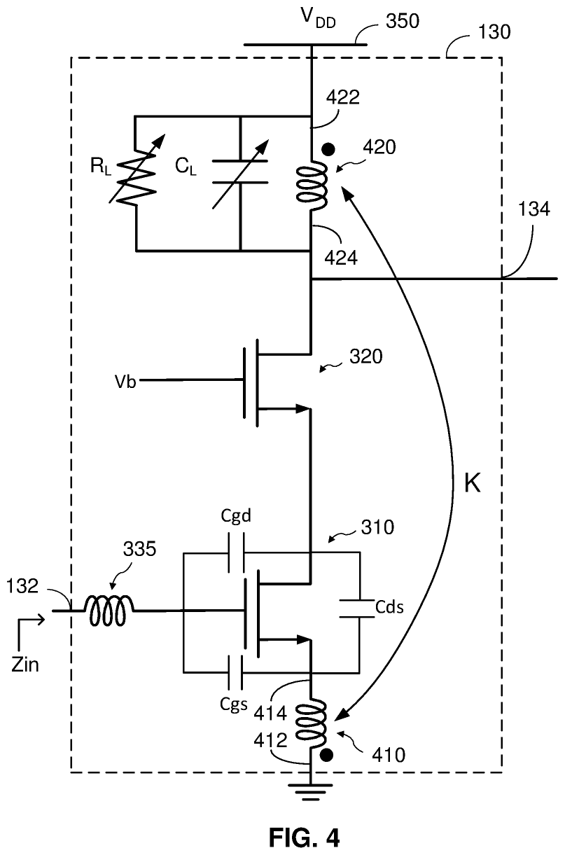

FIG. 4 shows an exemplary implementation of the LNA 130 according to certain aspects of the present disclosure. The LNA 130 includes the first transistor 310, the second transistor 320, and the gate inductor 335 discussed above with reference to FIG. 3. The LNA 130 also includes a source inductor 410 (also referred to as a degeneration inductor) and an output inductor 420 that are magnetically coupled with one another, as discussed further below. The source inductor 410 has a first terminal 412 coupled to a ground (or some reference potential) and a second terminal 414 coupled to the source of the first transistor 310. The source inductor 410 provides the first transistor 310 with source degeneration (e.g., to improve the linearity of the LNA 130). The output inductor 420 (also referred to as a load inductor) has a first terminal 422 coupled to the supply rail 350 and a second terminal 424 coupled to the output 134 of the LNA 130.

The gate inductor 335 is coupled between the input 132 of the LNA 130 and the gate of the first transistor 310. The source of the second transistor 320 is coupled to the drain of the first transistor 310, the gate of the second transistor 320 is biased by the bias voltage Vb, and the drain of the second transistor 320 is coupled to the output 134 of the LNA 130. In the example in FIG. 4, the first transistor 310 and the second transistor 320 are arranged in a cascode configuration with the first transistor 310 functioning as a common-source amplifier and the second transistor 320 functioning as a common-gate amplifier.

The LNA 130 may also include the tunable load capacitor C_{L} and/or the tunable load resistor R_{L} coupled in parallel with the output inductor 420 (e.g., to provide frequency selection and/or gain selection). However, it is to be appreciated that the tunable load capacitor C_{L} and/or the tunable load resistor R_{L} may be omitted in some implementations.

As discussed above, the output inductor 420 and the source inductor 410 are magnetically coupled (i.e., inductively coupled). The magnetic coupling may be achieved by physically placing the output inductor 420 and the source inductor 410 next to each other on a chip or a substrate (e.g., a laminate, a printed circuit board (PCB), etc.), as discussed further below.

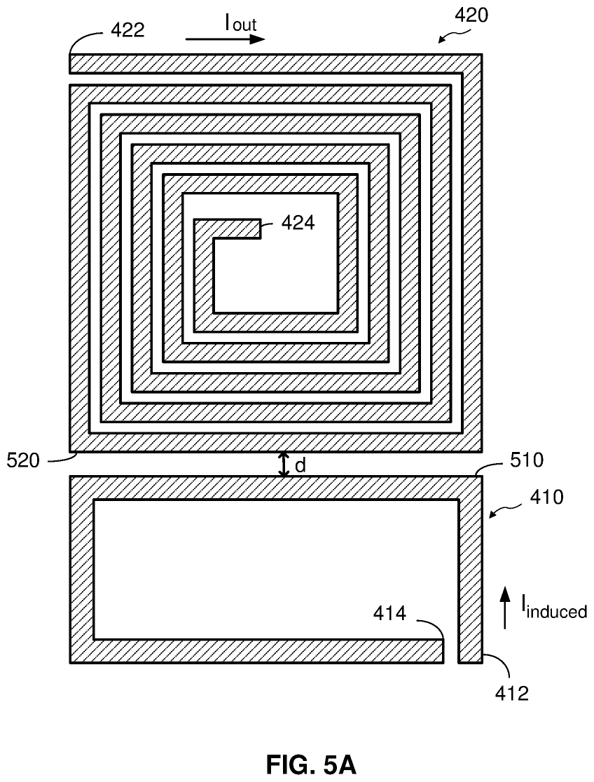

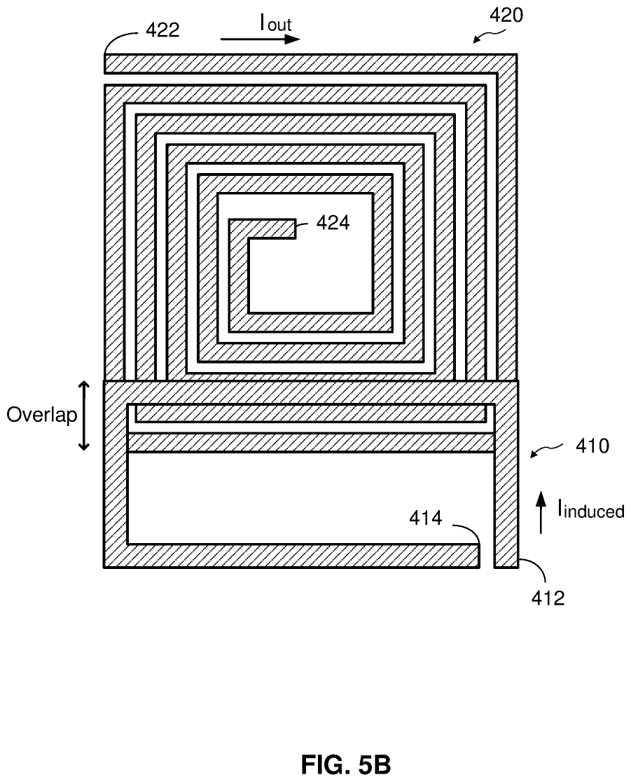

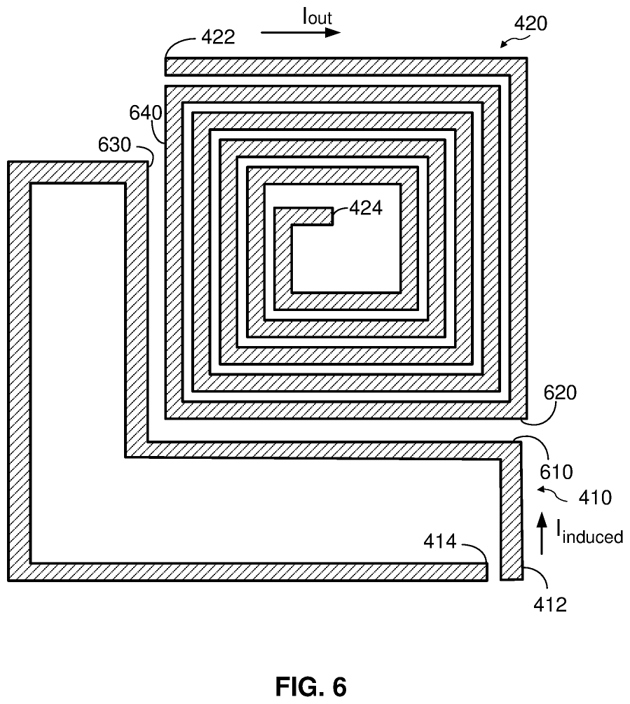

In FIG. 4, the magnetic coupling between the output inductor 420 and the source inductor 410 is indicated by the double arrow pointing to the output inductor 420 and the source inductor 410. The polarity of each inductor is indicated by the respective dot next to the inductor. In the example shown in FIG. 4, the dot next to the output inductor 420 is on the top and the dot next to the source inductor 410 is on the bottom, indicating that the output inductor 420 and the source inductor 410 have opposite polarities. Note that FIG. 4 shows a circuit schematic of the output inductor 420 and the source inductor 410, and not the physical locations of these inductors with respect to each other. Examples of physical implementations of the output inductor 420 and the source inductor 410 are discussed below with reference to FIGS. 5A, 5B, and 6.

The magnetic coupling between the output inductor 420 and the source inductor 410 induces a current in the source inductor 410 that is 180 degrees out of phase with the current in the output inductor 420 due to the opposite polarities of the output inductor 420 and the source inductor 410. The induced current flows from the source of the transistor 310 to the drain node, which at least partially cancels the effect of the gate-to-drain capacitance Cgd of the first transistor 310 on the input impedance Zin. This allows the real part of the input impedance Re(Zin) and the real part of the optimum impedance Re(Zopt) to be brought closer together to achieve both low NF and low return loss for the LNA 130. The induced current from the magnetic coupling also increases the effective gate-to-source capacitance Cgs of the first transistor 310, which allows input impedance matching using a smaller inductance (and hence smaller size) for the gate inductor 335. This reduces losses in the gate inductor 335, which also helps lower the NF of the LNA 130.

While the magnetic coupling between the output inductor 420 and the source inductor 410 helps lower the NF of the LNA 130, making the magnetic coupling too strong can lead to instability because the coupling provides positive feedback in the LNA 130. To prevent instability caused by the positive feedback, the magnetic coupling coefficient K of the magnetic coupling may be kept within a range that provides sufficient magnetic coupling to realize the above benefits of the magnetic coupling while avoiding instability caused by making the coupling coefficient K too high. For example, in some implementations, the coupling coefficient K may be within a range (i.e., K range) of between 0.05 and 0.30 to provide sufficient magnetic coupling to realize the above benefits of the magnetic coupling while avoiding instability caused by making the coupling coefficient K too high.

The upper bound of the K range may be defined by a maximum coupling coefficient (i.e., Kmax) that is below the coupling coefficient at which instability in the LNA 130 starts to occur. The coupling coefficient at which instability starts to occur may depend, for example, on the gain of the LNA 130, the reverse isolation (i.e., S12 parameter) of the LNA 130, and/or the operating frequency of the LNA 130. As a result, the maximum coupling coefficient may also depend on the gain of the LNA 130, the reverse isolation (i.e., S12 parameter) of the LNA 130, and/or the operating frequency of the LNA 130. For example, for a reverse isolation (i.e., S12 parameter) of −30 dB, the maximum coupling coefficient may be 0.15 at an operating frequency of 860 MHz, 0.20 at an operating frequency of 750 MHz, and 0.25 at an operating frequency of 700 MHz. However, it is to be appreciated that the present disclosure is not limited to this example. For implementations where the LNA 130 operates at multiple frequencies, the maximum coupling coefficient may be set to a coupling coefficient that avoids instability at all of the operating frequencies of the LNA 130. Thus, it is to be appreciated that the present disclosure is not limited to a particular K range. Examples of K ranges that avoid instability may include the K range between 0.05 and 0.30, a K range between 0.05 and 0.20, and a K range between 0.05 and 0.15. However, it is to be appreciated that the present disclosure is not limited to these examples.

In other words, the output inductor 420 and the source inductor 410 may be weakly magnetically coupled to realize the above benefits of the magnetic coupling while avoiding instability. The weak magnetic coupling may be achieved by placing the output inductor 420 and the source inductor 410 next to one another (e.g., on a chip or a substrate) or having the source inductor 410 partially overlap the output inductor 420 as opposed to placing the source inductor 410 within the output inductor 420 as is done to achieve a strong magnetic coupling.

FIG. 5A shows a top view of an exemplary physical layout of the output inductor 420 and the source inductor 410 according to certain aspects. In the example in FIG. 5A, the output inductor 420 includes a spiral inductor with the first terminal 422 located at one end of the spiral inductor and the second terminal 424 located at another end of the spiral inductor. For example, the spiral inductor may be a planar spiral inductor formed from a metal layer (e.g., using a lithographic and etching process). It is to be appreciated that the output inductor 420 is not limited to a spiral inductor and may be implemented with another type of inductor. For example, in other implementation, the output inductor 420 may include a single loop, multiple loops coupled in series and/or parallel, and the like.

The source inductor 410 may be implemented with a loop inductor, a spiral inductor, or another type of inductor. The source inductor 410 may be formed from the same metal layer as the output inductor 420 (e.g., using a lithographic and etching process) or formed from a different metal layer. The source inductor 410 and the output inductor 420 may be integrated on a chip (i.e., die) or may be formed on and/or embedded in a substrate (e.g., a laminate, a PCB, and the like).

In the example shown in FIG. 5A, the output inductor 420 is arranged next to the source inductor 410 such that a magnetic coupling is achieved between the output inductor 420 and the first source inductor 410. For example, the exemplary layout shown in FIG. 5A may provide a magnetic coupling coefficient K of approximately 0.08 or another magnetic coupling coefficient K (e.g., such as in one example within one of the exemplary K ranges discussed above). In the exemplary layout shown in FIG. 5A, one side 510 of the source inductor 410 is next to one side 520 of the output inductor 420. In this example, the side 520 of the output inductor 420 runs parallel with the side 510 of the source inductor 410. However, it is to be appreciated that the present disclosure is not limited to this example. In other implementations, the source inductor 410 may partially overlap the output inductor 420, as discussed further below.

In the example in FIG. 5A, the output inductor 420 and the source inductor 410 are arranged such that a space (labeled “d”) between the output inductor 420 and the source inductor 410 achieves a desired coupling coefficient K (e.g., such as in one example within one of the exemplary K ranges discussed above). For example, a higher coupling coefficient K may be achieved by making the space smaller, and a lower coupling coefficient may be achieved by making the space larger. For the example where the output inductor 420 and the source inductor 410 are formed in the same metal layer, the smallest possible space between the output inductor 420 and the source inductor 410 may be limited by a design rule specifying a minimum space between adjacent metal lines for a fabrication process used to fabricate the inductors 410 and 420. In the example in FIG. 5A, the space (labeled “d”) corresponds to the space between the side 520 of the output inductor 420 and the side 510 of the source inductor 410. However, it is to be appreciated that the present disclosure is not limited to this example. A space may also be referred to as spacing, a distance, or another term.

In the example in FIG. 5A, the output inductor 420 and the source inductor 410 are configured to produce the opposite polarities shown in FIG. 4. For example, the output inductor 420 and the source inductor 410 may be configured such that the magnetic coupling between the output inductor 420 and the source inductor 410 causes a current (labeled “Iₒᵤₜ”) in the output inductor 420 flowing from the first terminal 422 to the second terminal 424 to induce a current (labeled “I_{induced}”) in the source inductor 410 flowing from the first terminal 412 to the second terminal 414. In the example in FIG. 5A, this is achieved by winding the conductor path of the output inductor 420 (e.g., spiral inductor) in the clockwise direction from the first terminal 422 to the second terminal 424 and winding the conductor path of the source inductor 410 (e.g., loop inductor) in the counterclockwise direction from the first terminal 412 to the second terminal 414. However, it is to be appreciated that the present disclosure is not limited to this example. For example, in other implementations, the conductor path of the output inductor 420 (e.g., spiral inductor) may be wound in the counterclockwise direction from the first terminal 422 to the second terminal 424 and the conductor path of the source inductor 410 (e.g., loop inductor) may be wound in the clockwise direction from the first terminal 412 to the second terminal 414.

As discussed above, the source inductor 410 may partially overlap the output inductor 420 in some implementations. In this regard, FIG. 5B shows an exemplary layout in which the source inductor 410 partially overlaps the output inductor 420. For example, the source inductor 410 and the output inductor 420 may be arranged such that the partial overlap of the source inductor 410 and the output inductor 420 achieves a desired coupling coefficient K (e.g., such as in one example within one of the exemplary K ranges discussed above). In this example, the output inductor 420 may be formed from a first metal layer (e.g., using a lithographic and etching process) and the source inductor 410 may be formed from a second metal layer (e.g., using a lithographic and etching process) where the second metal layer is below or above the first metal layer.

FIG. 6 shows another exemplary implementation of the source inductor 410 according to certain aspects. In this example, the source inductor 410 is adjacent to the output inductor 420 on two sides. More particularly, a first side 610 of the source inductor 410 is adjacent to a first side 620 of the output inductor 420, and a second side 630 of the source inductor 410 is adjacent to a second side 640 of the output inductor 420 such that a desired coupling coefficient K is achieved (e.g., such as in one example within one of the exemplary K ranges discussed above). In the example shown in FIG. 6, the first side 620 of the output inductor 420 runs parallel with the first side 610 of the source inductor 410, and the second side 640 of the output inductor 420 runs parallel with the second side 630 of the source inductor 410. However, it is to be appreciated that the present disclosure is not limited to this example. The exemplary layout shown in FIG. 6 may provide a magnetic coupling coefficient K of approximately 0.18 or another magnetic coupling coefficient K (e.g., such as in one example within one of the exemplary K ranges discussed above).

In the example in FIG. 6, the output inductor 420 and the source inductor 410 are configured to produce the opposite polarities shown in FIG. 4. For example, the output inductor 420 and the source inductor 410 may be configured such that the magnetic coupling between the output inductor 420 and the source inductor 410 causes a current (labeled “Iₒᵤₜ”) in the output inductor 420 flowing from the first terminal 422 to the second terminal 424 to induce a current (labeled “I_{induced}”) in the source inductor 410 flowing from the first terminal 412 to the second terminal 414. In the example in FIG. 6, this is achieved by winding the conductor path of the output inductor 420 (e.g., spiral inductor) in the clockwise direction from the first terminal 422 to the second terminal 424 and winding the conductor path of the source inductor 410 (e.g., loop inductor) in the counterclockwise direction from the first terminal 412 to the second terminal 414. However, it is to be appreciated that the present disclosure is not limited to this example.

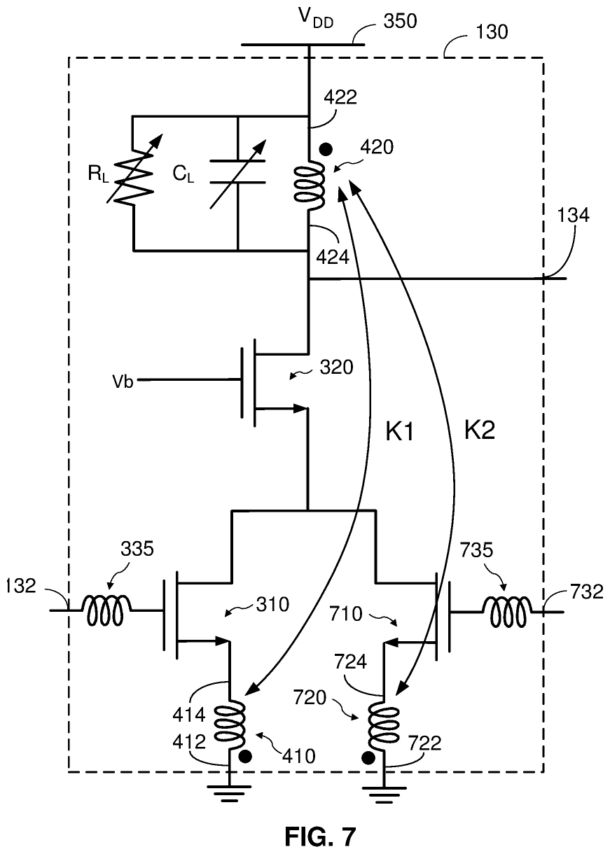

In certain aspects, the LNA 130 may include multiple inputs (e.g., for amplifying RF signals in different frequency bands). In this regard, FIG. 7 shows an exemplary implementation of the LNA 130 in which the LNA 130 includes multiple inputs according to certain aspects. In this example, the LNA 130 includes the first transistor 310, the second transistor 320, the gate inductor 335, the source inductor 410, and the output inductor 420 discussed above with reference to FIG. 4. The LNA 130 also includes a third transistor 710, a second source inductor 720, and a second gate inductor 735. In the discussion below, the source inductor 410 is referred to as the first source inductor, the gate inductor 335 is referred to as the first gate inductor, and the input 132 is referred to as the first input. The first source inductor 410 is magnetically coupled with the output inductor 420, as discussed above with reference to FIG. 4.

In this example, the second source inductor 720 is also coupled with the output inductor 420. In FIG. 7, the magnetic coupling coefficient between the first source inductor 410 and the output inductor 420 is labeled K1, and the magnetic coupling coefficient between the second source inductor 720 and the output inductor 420 is labeled K2. In certain aspects, the magnetic coupling coefficients K1 and K2 may each be within one of the exemplary K ranges discussed above such as the K range between 0.05 and 0.30, the K range between 0.05 and 0.20, and the K range between 0.05 and 0.15. However, it is to be appreciated that the present disclosure is not limited to this example. In general, the magnetic coupling coefficients K1 and K2 may each be within a K range that avoids instability in the LNA 130.

In the example in FIG. 7, the second source inductor 720 has a first terminal 722 coupled to a ground (or some reference potential) and a second terminal 724 coupled to the source of the third transistor 710. The second source inductor 720 provides the third transistor 710 with source degeneration (e.g., to improve the linearity of the LNA 130). The drain of the third transistor 710 is coupled to the source of the second transistor 320. Also, the second gate inductor 735 is coupled between the gate of the third transistor 710 and a second input 732 of the LNA 130 (e.g., to provide impedance matching at the second input 732).

In the example in FIG. 7, the first transistor 310 and the third transistor 710 share the second transistor 320 in which the first transistor 310 functions as a common-source amplifier for the first input 132 of the LNA 130, the third transistor 710 functions as a common-source amplifier for the second input 732 of the LNA 130, and the second transistor 320 functions as a common-gate amplifier. In certain aspects, the first input 132 may be configured to receive a first RF signal, and the second input 732 may be configured to receive a second RF signal, as discussed further below.

The LNA 130 may also include the tunable load capacitor C_{L} and/or the tunable load resistor R_{L} coupled in parallel with the output inductor 420 (e.g., to provide frequency selection and/or gain selection), as discussed above with reference to FIG. 4. However, it is to be appreciated that the tunable load capacitor C_{L} and/or the tunable load resistor R_{L} may be omitted in some implementations.

As discussed above, the second source inductor 720 is magnetically coupled (i.e., inductively coupled) with the output inductor 420. The magnetic coupling may be achieved by physically placing the second source inductor 720 next to the output inductor 420 on a chip or a substrate (e.g., a laminate, a printed circuit board (PCB), etc.), as discussed further below.

In FIG. 7, the magnetic coupling between the second source inductor 720 and the output inductor 420 is indicated by the double arrow pointing to the output inductor 420 and the second source inductor 720. The polarity of each of the inductors 420, 410, and 710 is indicated by the respective dot next to the inductor. In the example shown in FIG. 7, the dot next to the output inductor 420 is on the top and the dot next to the second source inductor 720 is on the bottom, indicating that the output inductor 420 and the second source inductor 720 have opposite polarities. The magnetic coupling between the output inductor 420 and the second source inductor 720 induces a current in the second source inductor 720 that is 180 degrees out of phase with the current in the output inductor 420 due to the opposite polarities of the output inductor 420 and the second source inductor 720. The induced current flows from the source of the third transistor 710 to the drain node, which at least partially cancels the effect of the gate-to-drain capacitance of the third transistor 710 on the input impedance Zin at the second input 732. Thus, the magnetic coupling between the second source inductor 720 and the output inductor 420 helps the LNA 130 achieve low NF and low return loss for the second input 732 of the LNA 130 in a manner similar to the manner discussed above for the first input 132 of the LNA. In some implementations, the coupling coefficient K2 may be within one of the exemplary K ranges discussed above to provide sufficient magnetic coupling to achieve low NF and low return loss for the second input 732 while avoiding instability caused by making the coupling coefficient K2 too high.

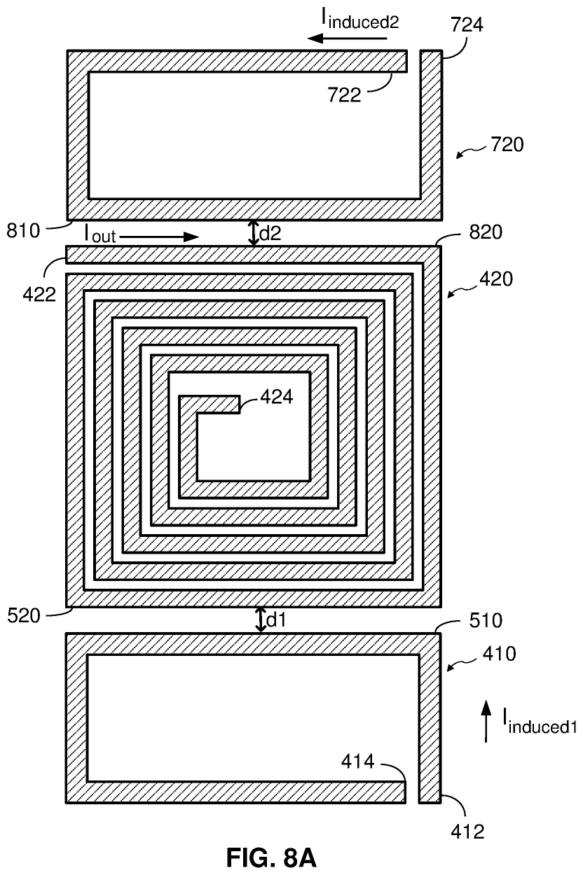

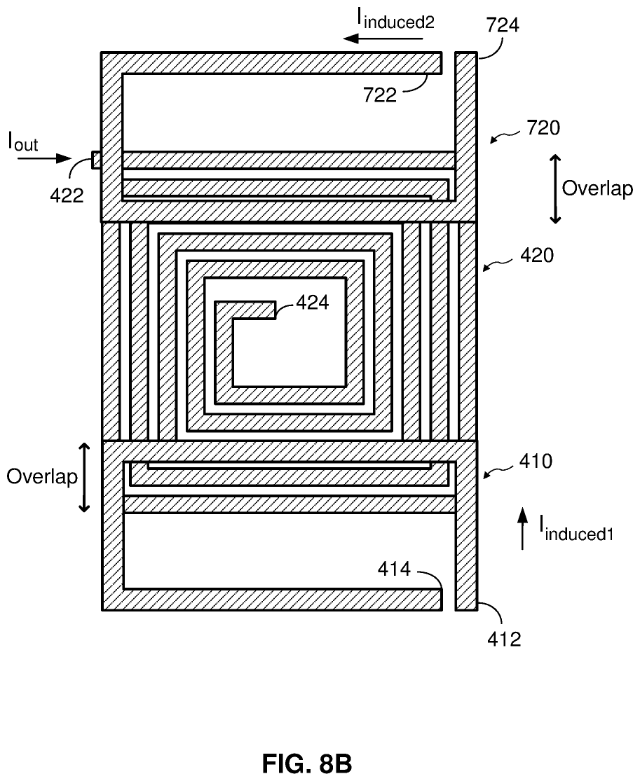

FIG. 8A shows a top view of an exemplary physical layout of the output inductor 420, the first source inductor 410, and the second source inductor 720 according to certain aspects. In the example in FIG. 8A, the output inductor 420 includes the exemplary spiral inductor discussed above with reference to FIG. 5A. However, it is to be appreciated that the output inductor 420 is not limited to this example. For example, in other implementation, the output inductor 420 may include a single loop, multiple loops coupled in series, and the like.

Each of the first source inductor 410 and the second source inductor 720 may be implemented with a respective loop inductor or a respective spiral inductor. The first source inductor 410 and the second source inductor 720 may be formed from the same metal layer as the output inductor 420 (e.g., using a lithographic and etching process) or formed from a different metal layer. The first source inductor 410, the second source inductor 720, and the output inductor 420 may be integrated on a chip (i.e., die) or may be formed on and/or embedded in a substrate (e.g., a laminate, a PCB, and the like).

In the example shown in FIG. 8A, the first source inductor 410 is arranged next to the output inductor 420 such that a magnetic coupling is achieved between the output inductor 420 and the first source inductor 410, and the second source inductor 720 is arranged next to the output inductor 420 such that a magnetic coupling is achieved between the output inductor 420 and the second source inductor 720. In this example, the coupling coefficient K1 for the magnetic coupling between the first source inductor 410 and the output inductor 420 and the coupling coefficient K2 for the magnetic coupling between the second source inductor 720 and the output inductor 420 may each be within one of the exemplary K ranges discussed above or another K range.

In the example shown in FIG. 8A, one side 510 of the first source inductor 410 is adjacent to a first side 520 of the output inductor 420, and one side 810 of the second source inductor 720 is adjacent to a second side 820 of the output inductor 420. The first side 520 of the output inductor 420 and the second side 820 of the output inductor 420 may be opposite sides (i.e., opposing sides) of the output inductor 420, as shown in the example in FIG. 8A. However, it is to be appreciated that the present disclosure is not limited to this example. In other implementations, the first source inductor 410 may partially overlap the output inductor 420 and/or the second source inductor 720 may partially overlap the output inductor 420.

In the example in FIG. 8A, the output inductor 420 and the first source inductor 410 are arranged such that a first space (labeled “d1”) between the output inductor 420 and the first source inductor 410 achieves a desired coupling coefficient K1 (e.g., such as in one example within one of the exemplary K ranges discussed above). For example, a higher coupling coefficient K1 may be achieved by making the first space smaller, and a lower coupling coefficient may be achieved by making the first space larger. Also, the output inductor 420 and the second source inductor 720 are arranged such that a second space (labeled “d2”) between the output inductor 420 and the second source inductor 720 achieves a desired coupling coefficient K2 (e.g., such as in one example within one of the exemplary K ranges discussed above). For example, a higher coupling coefficient K2 may be achieved by making the second space smaller, and a lower coupling coefficient may be achieved by making the second space larger. In the example in FIG. 8A, the first space (labeled “d1”) corresponds to the space between the first side 520 of the output inductor 420 and the side 510 of the first source inductor 410, and the second space (labeled “d2”) corresponds to the space between the second side 820 of the output inductor 420 and the side 810 of the second source inductor 720. However, it is to be appreciated that the present disclosure is not limited to this example.

In the example in FIG. 8A, the output inductor 420 and the first source inductor 410 are configured to produce the opposite polarities shown in FIG. 7. For example, the output inductor 420 and the first source inductor 410 may be configured such that the magnetic coupling between the output inductor 420 and the first source inductor 410 causes a current (labeled “Iₒᵤₜ”) in the output inductor 420 flowing from the first terminal 422 to the second terminal 424 to induce a current (labeled “I_{induced1}”) in the first source inductor 410 flowing from the first terminal 412 to the second terminal 414. In the example in FIG. 8A, this is achieved by winding the conductor path of the output inductor 420 (e.g., spiral inductor) in the clockwise direction from the first terminal 422 to the second terminal 424 and winding the conductor path of the first source inductor 410 (e.g., loop inductor) in the counterclockwise direction from the first terminal 412 to the second terminal 414. However, it is to be appreciated that the present disclosure is not limited to this example.

In the example in FIG. 8A, the output inductor 420 and the second source inductor 720 are configured to produce the opposite polarities shown in FIG. 7. For example, the output inductor 420 and the second source inductor 720 may be configured such that the magnetic coupling between the output inductor 420 and the second source inductor 720 causes a current (labeled “Iₒᵤₜ”) in the output inductor 420 flowing from the first terminal 422 to the second terminal 424 to induce a current (labeled “I_{induced2}”) in the second source inductor 720 flowing from the first terminal 722 to the second terminal 724. In the example in FIG. 8A, this is achieved by winding the conductor path of the output inductor 420 (e.g., spiral inductor) in the clockwise direction from the first terminal 422 to the second terminal 424 and winding the conductor path of the second source inductor 720 (e.g., loop inductor) in the counterclockwise direction from the first terminal 722 to the second terminal 724. However, it is to be appreciated that the present disclosure is not limited to this example.

In FIG. 8B shows an exemplary layout in which the first source inductor 410 partially overlaps the output inductor 420, and the second source inductor 720 partially overlaps the output inductor 420. For example, the first source inductor 410 and the output inductor 420 may be arranged such that the partial overlap of the first source inductor 410 and the output inductor 420 achieves a desired coupling coefficient K1 (e.g., such as in one example within one of the exemplary K ranges discussed above). Also, the second source inductor 720 and the output inductor 420 may be arranged such that the partial overlap of the second source inductor 720 and the output inductor 420 achieves a desired coupling coefficient K2 (e.g., such as in one example within one of the exemplary K ranges discussed above). In this example, the output inductor 420 may be formed from a first metal layer (e.g., using a lithographic and etching process) and each of the first source inductor 410 and the second source inductor 720 may be formed from a second metal layer (e.g., using a lithographic and etching process) where the second metal layer is below or above the first metal layer. Note that the first terminal 422 of the output inductor 420 is shown extending slightly to the left of the second source inductor 720 in FIG. 8B so that the first terminal 422 is visible in FIG. 8B.

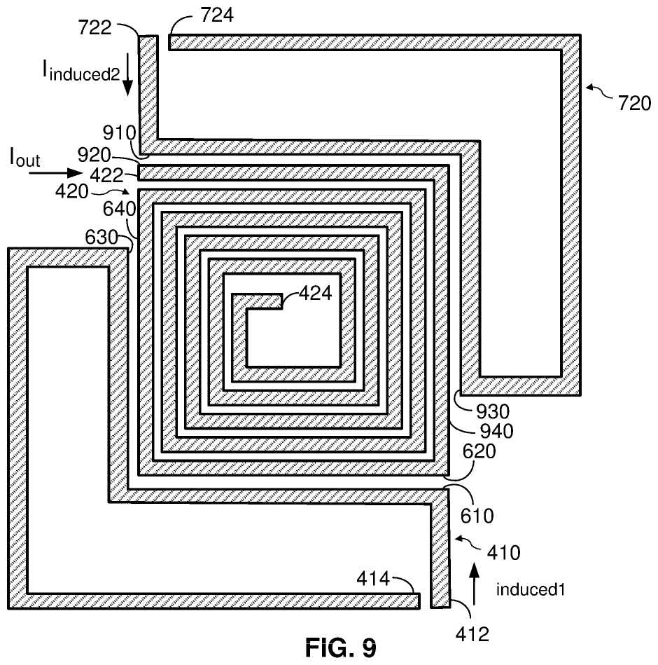

FIG. 9 shows another exemplary implementation of the first source inductor 410 and the second source inductor 720 according to certain aspects. In this example, the first source inductor 410 is adjacent to the output inductor 420 on two sides, and the second source inductor 720 is adjacent to the output inductor 420 on two sides. More particularly, in this example, a first side 610 of the first source inductor 410 is adjacent to a first side 620 of the output inductor 420, and a second side 630 of the first source inductor 410 is adjacent to a second side 640 of the output inductor 420 such that a desired coupling coefficient K1 is achieved (e.g., such as in one example within one of the exemplary K ranges discussed above). Also, in this example, a first side 910 of the second source inductor 720 is adjacent to a third side 920 of the output inductor 420, and a second side 930 of the second source inductor 720 is adjacent to a fourth side 940 of the output inductor 420 such that a desired coupling coefficient K2 is achieved (e.g., such as in one example within one of the exemplary K ranges discussed above). The first side 620 and the third side 920 of the output inductor 420 may be opposing sides of the output inductor 420, and the second side 640 and the fourth side 940 of the output inductor 420 may be opposing sides of the output inductor 420. However, it is to be appreciated that the present disclosure is not limited to this example.

In the example in FIG. 9, the output inductor 420 and the first source inductor 410 are configured to produce the opposite polarities shown in FIG. 7. For example, the output inductor 420 and the first source inductor 410 may be configured such that the magnetic coupling between the output inductor 420 and the first source inductor 410 causes a current (labeled “Iₒᵤₜ”) in the output inductor 420 flowing from the first terminal 422 to the second terminal 424 to induce a current (labeled “I_{induced1}”) in the first source inductor 410 flowing from the first terminal 412 to the second terminal 414. In the example in FIG. 9, this is achieved by winding the conductor path of the output inductor 420 (e.g., spiral inductor) in the clockwise direction from the first terminal 422 to the second terminal 424 and winding the conductor path of the first source inductor 410 (e.g., loop inductor) in the counterclockwise direction from the first terminal 412 to the second terminal 414. However, it is to be appreciated that the present disclosure is not limited to this example.

In the example in FIG. 9, the output inductor 420 and the second source inductor 720 are configured to produce the opposite polarities shown in FIG. 7. For example, the output inductor 420 and the second source inductor 720 may be configured such that the magnetic coupling between the output inductor 420 and the second source inductor 720 causes a current (labeled “Iₒᵤₜ”) in the output inductor 420 flowing from the first terminal 422 to the second terminal 424 to induce a current (labeled “I_{induced2}”) in the second source inductor 720 flowing from the first terminal 722 to the second terminal 724. In the example in FIG. 9, this is achieved by winding the conductor path of the output inductor 420 (e.g., spiral inductor) in the clockwise direction from the first terminal 422 to the second terminal 424 and winding the conductor path of the second source inductor 720 (e.g., loop inductor) in the counterclockwise direction from the first terminal 722 to the second terminal 724. However, it is to be appreciated that the present disclosure is not limited to this example.

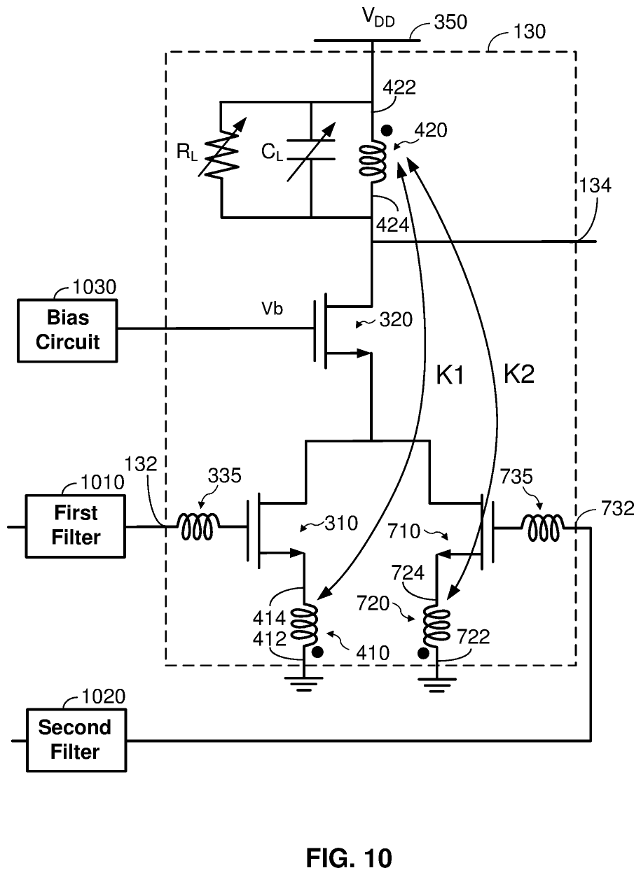

As discussed above, the first input 132 of the LNA 130 may be configured to receive the first RF signal and the second input 732 of the LNA 130 may be configured to receive the second RF signal. In certain aspects, the first RF signal may be within a first frequency band and the second RF signal may be within a second frequency band different from the first frequency band. In this regard, FIG. 10 shows an example in which the first input 132 may be coupled to a first filter 1010 (e.g., first bandpass filter) configured to pass signals in the first frequency band, and the second input 732 may be coupled to a second filter 1020 (e.g., second bandpass filter) configured to pass signals in the second frequency band.

FIG. 10 also shows an example of a bias circuit 1030 coupled to the gate of the second transistor 320. The bias circuit 1030 is configured to output the bias voltage Vb to the gate of the second transistor 320. The bias circuit 1030 may be implemented with a voltage divider (e.g., resistive voltage divider), a bandgap reference circuit, or any other bias circuit known in the art.

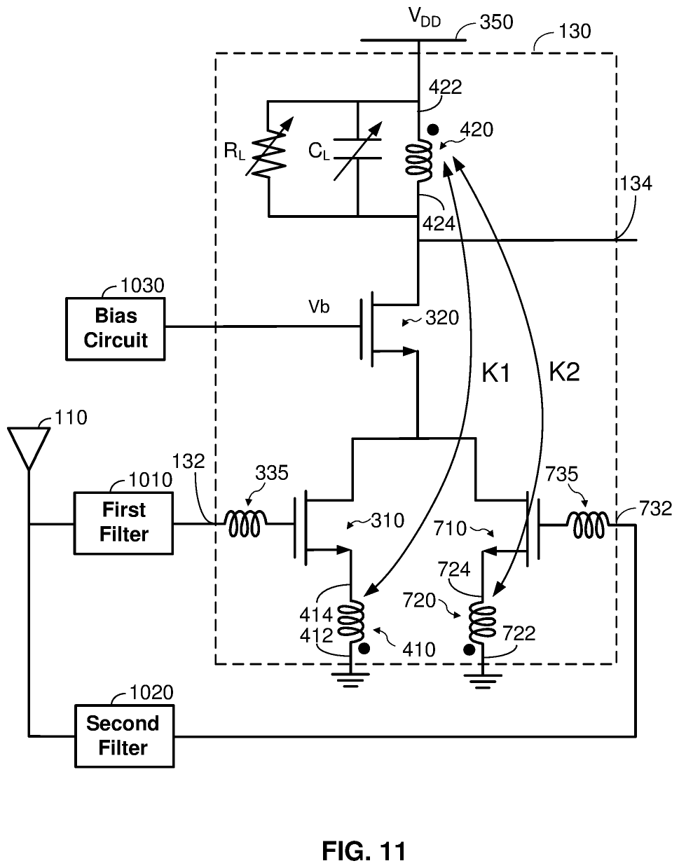

In some implementations, the first filter 1010 and the second filter 1020 are both coupled to the antenna 110 to receive the respective RF signals via the antenna 110, an example of which is shown in FIG. 11. In the example shown in FIG. 11, the first filter 1010 is coupled between the antenna 110 and the first input 132 of the LNA 130, and the second filter 1020 is coupled between the antenna 110 and the second input 732 of the LNA 130.

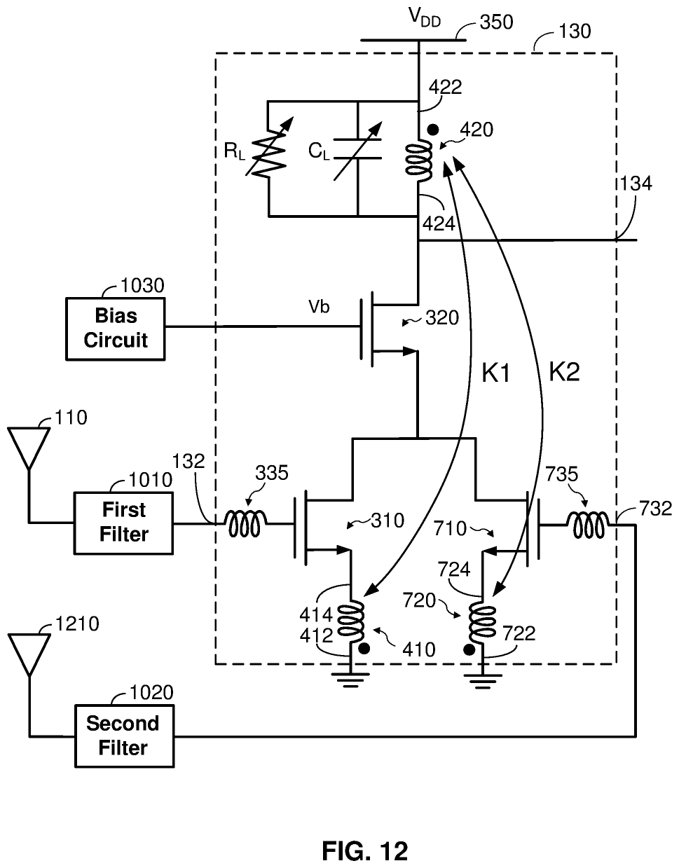

In other implementations, the first filter 1010 and the second filter 1020 are coupled to different antennas to receive the respective RF signals, an example of which is shown in FIG. 12. In the example shown in FIG. 12, the first filter 1010 is coupled between the antenna 110 and the first input 132 of the LNA 130, and the second filter 1020 is coupled between a second antenna 1210 and the second input 732 of the LNA 130. In this example, the antenna 110 may also be referred to as the first antenna.

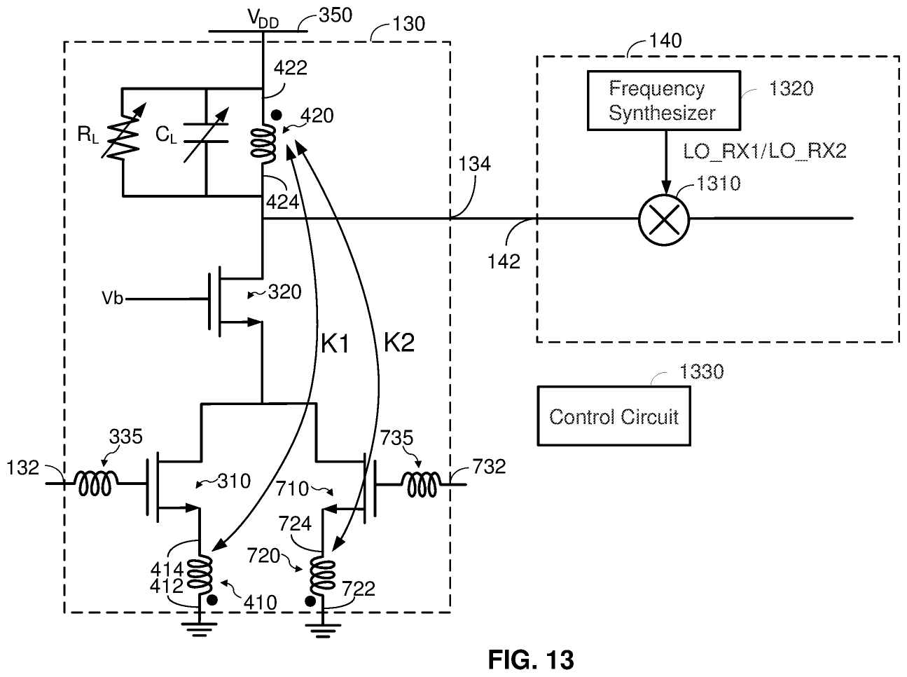

FIG. 13 shows an example in which the output 134 of the LNA 130 is coupled to the receiver 140 discussed above. In this example, the receiver 140 includes a frequency synthesizer 1320 and a mixer 1310 coupled to the output 134 of the LNA 130. The frequency synthesizer 1320 is configured to generate one or more oscillator signals for frequency down conversion, as discussed further below.

In this example, the LNA 130 may receive the first RF signal and the second RF signal one at a time. When the LNA 130 receives the first RF signal, the frequency synthesizer 1320 generates a first local oscillator signal (labeled “LO_RX1”) and outputs the first local oscillator signal to the mixer 1310. The mixer 1310 mixes the first RF signal from the LNA 130 with the first local oscillator signal to frequency down-convert the first RF signal to a first baseband signal or a first intermediate frequency (IF) signal. The first baseband signal or the first IF signal may be sent to additional components in the receiver 140 and/or a modem for further processing.

When the LNA 130 receives the second RF signal, the frequency synthesizer 1320 generates a second local oscillator signal (labeled “LO_RX2”) and outputs the second local oscillator signal to the mixer 1310. The mixer 1310 mixes the second RF signal from the LNA 130 with the second local oscillator signal to frequency down-convert the second RF signal to a second baseband signal or a second IF signal. The second baseband signal or the second IF signal may be sent to additional components in the receiver 140 and/or a modem for further processing.

In certain aspects, the LNA 130 may be configured to amplify signals in a tunable frequency band. In these aspects, the system may include a control circuit 1330 configured to tune the frequency band of the LNA 130 by tuning the capacitance of the load capacitor C_{L} and/or the tuning resistance of the load resistor R_{L} accordingly. When the LNA 130 receives the first RF signal in the first frequency band, the control circuit 1330 may be configured to tune the frequency band of the LNA 130 such that the first frequency band of the first RF signal is within the frequency band of the LNA 130. When the LNA 130 receives the second RF signal in the second frequency band, the control circuit 1330 may be configured to tune the frequency band of the LNA 130 such that the second frequency band of the second RF signal is within the frequency band of the LNA 130. In other implementations, the frequency band of the LNA 130 may be a wide frequency band such that the first frequency band and the second frequency band are both within the frequency band of the LNA 130 without the need for tuning the frequency band of the LNA 130 when switching between reception of the first RF signal and reception of the second RF signal.

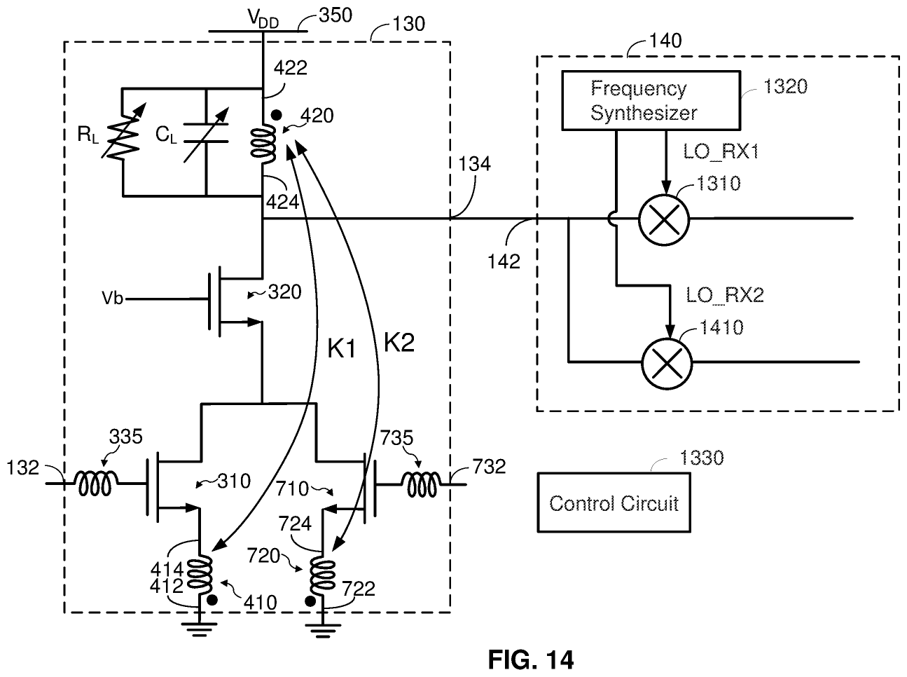

FIG. 14 shows an example in which the receiver 140 includes a second mixer 1410 coupled to the output 134 of the LNA 130. In this example, the second mixer 1410 allows the receiver 140 to simultaneously receive the first RF signal and the second RF signal from the LNA 130. In the discussion below, the mixer 1310 is referred to as the first mixer 1310.

In this example, the frequency synthesizer 1320 outputs the first local oscillator signal (labeled “LO_RX1”) to the first mixer 1310 and outputs the second local oscillator signal (labeled “LO_RX2”) to the second mixer 1410. The first mixer 1310 mixes the first RF signal with the first local oscillator signal to frequency down convert the first RF signal into the first baseband signal or first IF signal discussed above. The second mixer 1410 mixes the second RF signal with the second local oscillator signal to frequency down convert the second RF signal into the second baseband signal or second IF signal discussed above. Also, in this example, the frequency band of the LNA 130 may be a wide frequency band such that the first frequency band and the second frequency band are both within the frequency band of the LNA 130. The wide frequency band allows the LNA 130 to simultaneously amplify signals in the first frequency and the second frequency band.

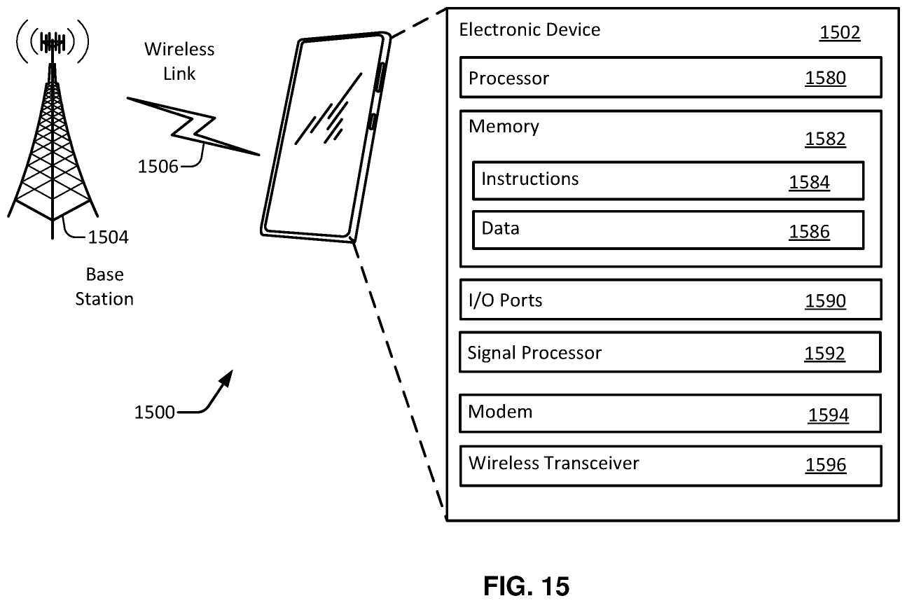

FIG. 15 is a diagram of an environment 1500 that includes an electronic device 1502 and a base station 1504. The electronic device 1502 may include the system 105 including one or more of the antennas 110 and 1210, one or more of the first filter 1010 and the second filter 1020, the LNA 130, and the receiver 140.

In the environment 1500, the electronic device 1502 communicates with the base station 1504 via a wireless link 1506. As shown, the electronic device 1502 is depicted as a smart phone. However, the electronic device 1502 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, and so forth.

The base station 1504 communicates with the electronic device 1502 via the wireless link 1506, which may be implemented as any suitable type of wireless link. Although depicted as a base station tower of a cellular radio network, the base station 1504 may represent or be implemented as another device, such as a satellite, terrestrial broadcast tower, access point, peer to peer device, mesh network node, fiber optic line, another electronic device generally as described above, and so forth. Hence, the electronic device 1502 may communicate with the base station 1504 or another device via a wired connection, a wireless connection, or a combination thereof. The wireless link 1506 can include a downlink of data or control information communicated from the base station 1504 to the electronic device 1502 and an uplink of other data or control information communicated from the electronic device 1502 to the base station 1504. The wireless link 1506 may be implemented using any suitable communication protocol or standard, such as 3rd Generation Partnership Project Long-Term Evolution (3GPP LTE, 3GPP NR 5G), IEEE 1502.15, IEEE 1502.15, Bluetooth™, and so forth.

The electronic device 1502 includes a processor 1580 and a memory 1582. The memory 1582 may be or form a portion of a computer readable storage medium. The processor 1580 may include any type of processor, such as an application processor or a multi-core processor, that is configured to execute processor-executable instructions (e.g., code) stored in the memory 1582. The memory 1582 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the memory 1582 is implemented to store instructions 1584, data 1586, and other information of the electronic device 1502.

The electronic device 1502 may also include input/output (I/O) ports 1590. The I/O ports 1590 enable data exchanges or interaction with other devices, networks, or users or between components of the device.

The electronic device 1502 may further include a signal processor (SP) 1592 (e.g., such as a digital signal processor (DSP)). The signal processor 1592 may function similar to the processor 1580 and may be capable of executing instructions and/or processing information in conjunction with the memory 1582.

For communication purposes, the electronic device 1502 also includes a modem 1594 and a wireless transceiver 1596, which may include the receiver 140. The wireless transceiver 1596 provides connectivity to respective networks and other electronic devices connected therewith using RF wireless signals. The wireless transceiver 1596 may facilitate communication over any suitable type of wireless network, such as a wireless local area network (LAN) (WLAN), a peer to peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

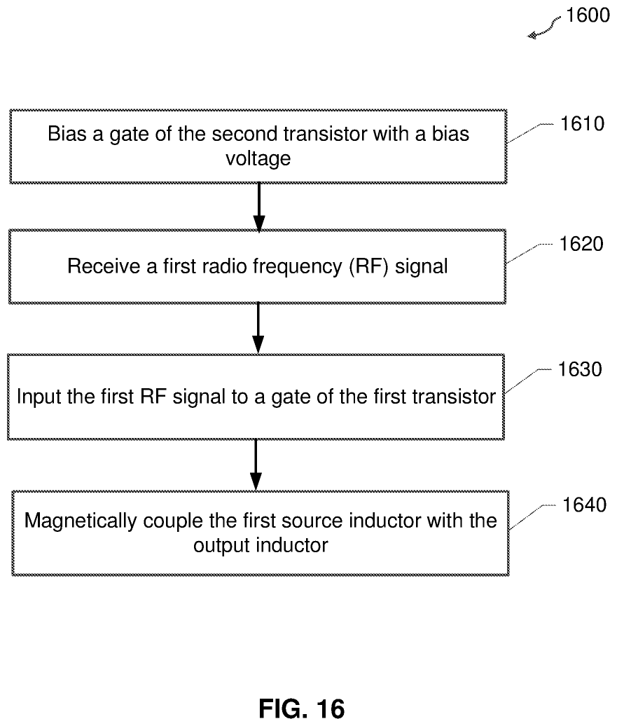

FIG. 16 shows an example of a method 1600 for operating a wireless communications system including a low-noise amplifier (LNA). The LNA (e.g., LNA 130) includes a first transistor (e.g., first transistor 310), a first source inductor (e.g., first source inductor 410) coupled to a source of the first transistor, a second transistor (e.g., second transistor 320) coupled between an output (e.g., output 134) of the LNA and a drain of the first transistor, and an output inductor (e.g., output inductor 420) coupled between a supply rail (e.g., supply rail 350) and the output of the LNA.

At block 1610, a gate of the second transistor is biased with a bias voltage. For example, the bias circuit 1030 may bias the gate of the second transistor with the bias voltage Vb.

At block 1620, a first radio frequency (RF) signal in a first frequency band is received. For example, the first RF signal may be received via the antenna 110. In certain aspects, the received first RF signal may be filtered by the first filter 1010.

At block 1630, the first RF signal is input to a gate of the first transistor. For example, the first RF signal may be input to the gate of the first transistor via the input 132.

At block 1640, the first source inductor is magnetically coupled with the output inductor. For example, the first source inductor may be magnetically coupled with the output inductor by placing the first source inductor next to the output inductor or having the first source inductor partially overlap the output inductor.

In certain aspects, magnetically coupling the first source inductor with the output inductor may include magnetically coupling the first source inductor with the output inductor with a magnetic coupling coefficient between 0.05 and 0.3, within one of the exemplary K ranges discussed above, or within another K range.

In certain aspects, the LNA further includes a third transistor (e.g., third transistor 710), and a second source inductor (e.g., second source inductor 720) coupled to a source of the third transistor, wherein the second transistor is coupled between the output of the LNA and a drain of the third transistor. In these aspects, the method 1600 may also include receiving a second RF signal in a second frequency band, inputting the second RF signal to a gate of the third transistor, and magnetically coupling the second source inductor with the output inductor.

In certain aspects, magnetically coupling the first source inductor with the output inductor includes magnetically coupling the first source inductor with the output inductor with a first magnetic coupling coefficient between 0.05 and 0.30, within one of the exemplary K ranges discussed above, or within another K range. Also, magnetically coupling the second source inductor with the output inductor includes magnetically coupling the second source inductor with the output inductor with a second magnetic coupling coefficient between 0.05 and 0.30, within one of the exemplary K ranges discussed above, or within another K range.

The method 1600 may also include filtering the first RF signal using a first bandpass filter before inputting the first RF signal to the gate of the first transistor, and filtering the second RF signal using a second bandpass filter before inputting the second RF signal to the gate of the third transistor. The first bandpass filter may correspond to the first filter 1010 and the second bandpass filter may correspond to the second filter 1020.

Implementation examples are described in the following numbered clauses:
1. A system for wireless communications, comprising:
   a low-noise amplifier (LNA), comprising:
      a first transistor;
      a first source inductor coupled to a source of the first transistor;
      a second transistor, wherein a source of the second transistor is coupled to a drain of the first transistor, a gate of the second transistor is coupled to a bias circuit, and a drain of the second transistor is coupled to an output of the LNA; and
      an output inductor coupled between a supply rail and the output of the LNA, wherein the output inductor is magnetically coupled with the first source inductor.
2. The system of clause 1, wherein the output inductor is arranged next to the first source inductor to achieve a magnetic coupling between the output inductor and the first source inductor.
3. The system of clause 1 or 2, wherein a magnetic coupling coefficient between the output inductor and the first source inductor is between 0.05 and 0.3.
4. The system of any one of clauses 1 to 3, wherein the first source inductor is placed next to the output inductor.
5. The system of clause 4, wherein at least one side of the first source inductor is adjacent to at least one side of the output inductor.
6. The system of any one of clauses 1 to 5, wherein the first source inductor and the output inductor have opposite polarities.
7. The system of any one of clauses 1 to 6, wherein the first source inductor and the output inductor are weakly magnetically coupled.
8. The system of any one of clauses 1 to 7, further comprising a filter coupled to a gate of the first transistor.
9. The system of clause 8, wherein the LNA further comprises a gate inductor coupled between the filter and the gate of the first transistor.
10. The system of any one of clauses 1, 3, and 6 to 9, wherein the first source inductor partially overlaps the output inductor.
11. The system of any one of clauses 1 to 10, wherein the first source inductor is coupled between the source of the first transistor and a ground.
12. The system of any one of clauses, 1, 3, 6 to 9, and 11, wherein the LNA further comprises:
   a third transistor, wherein a drain of the third transistor is coupled to the source of the second transistor; and
   a second source inductor coupled to a source of the third transistor, wherein the output inductor is magnetically coupled with the second source inductor.
13. The system of clause 12, wherein the output inductor is arranged next to the second source inductor to achieve a magnetic coupling between the output inductor and the second source inductor.
14. The system of clause 12 or 13, wherein a first magnetic coupling coefficient between the output inductor and the first source inductor is between 0.05 and 0.3, and a second magnetic coupling coefficient between the output inductor and the second source inductor is between 0.05 and 0.3.
15. The system of any one of clauses 12 to 14, wherein each of the first source inductor and the second source inductor is placed next to the output inductor.
16. The system of clause 15, wherein a first side of the output inductor is adjacent to the first source inductor, and a second side of the output inductor is adjacent to the second source inductor.
17. The system of clause 16, wherein the first side and the second side are opposing sides of the output inductor.
18. The system of any one of clauses 12 to 17, wherein the first source inductor and the output inductor have opposite polarities, and the second source inductor and the output inductor have opposite polarities.
19. The system of any one of clauses 12 to 18, further comprising:
   a first filter coupled to a gate of the first transistor; and
   a second filter coupled to a gate of the third transistor.
20. The system of clause 19, wherein:
   the first filter is a first bandpass filter configured to pass a first radio frequency (RF) signal in a first frequency band; and
   the second filter is a second bandpass filter configured to pass a second RF signal in a second frequency band different from the first frequency band.
21. The system of clause 19 or 20, wherein the LNA further comprises:
   a first gate inductor coupled between the first filter and the gate of the first transistor; and
   a second gate inductor coupled between the second filter and the gate of the third transistor.
22. The system of any one of clauses 12 to 21, further comprising one or more mixers coupled to the output of the LNA.
23. The system of any one of clause 12, 14, and 18 to 22, wherein the first source inductor partially overlaps the output inductor, and the second source inductor partially overlaps the output inductor.
24. The system of any one of clauses 12 to 23, wherein the first source inductor is coupled between the source of the first transistor and a ground, and the second source inductor is coupled between the source of the third transistor and the ground.
25. A system for wireless communications, comprising:
   a radio frequency front-end (RFFE) circuit coupled to one or more antennas and comprising:
      a low-noise amplifier (LNA), comprising:
         a first transistor;
         a first source inductor coupled to a source of the first transistor;
         a second transistor, wherein a source of the second transistor is coupled to a drain of the first transistor, a gate of the second transistor is coupled to a bias circuit, and a drain of the second transistor is coupled to an output of the LNA; and
         an output inductor coupled between a supply rail and the output of the LNA, wherein the output inductor is magnetically coupled with the first source inductor; and
   a receiver coupled to the output of the LNA.
26. The system of clause 25, wherein the output inductor is arranged next to the first source inductor to achieve a magnetic coupling between the output inductor and the first source inductor.
27. The system of clause 25 or 26, wherein a magnetic coupling coefficient between the output inductor and the first source inductor is between 0.05 and 0.30.
28. The system of any one of clauses 25 to 27, wherein the first source inductor is placed next to the output inductor.
29. The system of clause 28, wherein at least one side of the first source inductor is adjacent to at least one side of the output inductor.
30. The system of any one of clauses 25 to 29, wherein the first source inductor and the output inductor have opposite polarities.
31. The system of any one of clauses 25 to 30, wherein the first source inductor and the output inductor are weakly magnetically coupled.
32. The system of any one of clauses 25 to 31, wherein the first source inductor is coupled between the source of the first transistor and a ground.
33. The system of any one of clauses 25, 27, and 30-32, wherein the first source inductor partially overlaps the output inductor.
34. The system of any one of clauses 25, 27, and 30-32, wherein the LNA further comprises:
   a third transistor, wherein a drain of the third transistor is coupled to the source of the second transistor; and
   a second source inductor coupled to a source of the third transistor, wherein the output inductor is magnetically coupled with the second source inductor.
35. The system of clause 34, wherein a first magnetic coupling coefficient between the output inductor and the first source inductor is between 0.05 and 0.3, and a second magnetic coupling coefficient between the output inductor and the second source inductor is between 0.05 and 0.3.
36. The system of clause 34 or 35, wherein each of the first source inductor and the second source inductor is placed next to the output inductor.
37. The system of clause 36, wherein a first side of the output inductor is adjacent to the first source inductor, and a second side of the output inductor is adjacent to the second source inductor.
38. The system of clause 37, wherein the first side and the second side are opposing sides of the output inductor.
39. The system of any one of clauses 34 to 38, wherein the first source inductor and the output inductor have opposite polarities, and the second source inductor and the output inductor have opposite polarities.
40. The system of any one of clauses 34 to 39, further comprising:
   a first filter coupled to a gate of the first transistor; and
   a second filter coupled to a gate of the third transistor.
41. The system of clause 40, wherein:
   the first filter is a first bandpass filter configured to pass a first radio frequency (RF) signal in a first frequency band; and
   the second filter is a second bandpass filter configured to pass a second RF signal in a second frequency band different from the first frequency band.
42. The system of clause 41, wherein the one or more antennas comprise a first antenna and a second antenna, the first filter is coupled between the first antenna and the gate of the first transistor, and the second filter is coupled between the second antenna and the gate of the third transistor.
43. The system of any one of clauses 40 to 42, wherein the LNA further comprises:
   a first gate inductor coupled between the first filter and the gate of the first transistor; and
   a second gate inductor coupled between the second filter and the gate of the third transistor.
44. The system of any one of clauses 34 to 43, wherein the receiver comprises one or more mixers coupled to the output of the LNA.
45. The system of any one of clauses 34, 35, and 39 to 44, wherein the first source inductor partially overlaps the output inductor, and the second source inductor partially overlaps the output inductor.
46. The system of any one of clauses 34 to 45, wherein the first source inductor is coupled between the source of the first transistor and a ground, and the second source inductor is coupled between the source of the third transistor and the ground.
47. A method for operating a wireless communications system including a low-noise amplifier (LNA), the LNA comprising a first transistor, a first source inductor coupled to a source of the first transistor, a second transistor coupled between an output of the LNA and a drain of the first transistor, and an output inductor coupled between a supply rail and the output of the LNA, the method comprising:
   biasing a gate of the second transistor with a bias voltage;
   receiving a first radio frequency (RF) signal in a first frequency band;
   inputting the first RF signal to a gate of the first transistor; and
   magnetically coupling the first source inductor with the output inductor.
48. The method of clause 47, wherein the output inductor is arranged next to the first source inductor to achieve a magnetic coupling between the output inductor and the first source inductor.
49. The method of clause 47 or 48, wherein magnetically coupling the first source inductor with the output inductor comprises magnetically coupling the first source inductor with the output inductor with a magnetic coupling coefficient between 0.05 and 0.3.
50. The method of any one of clauses 47 to 49, wherein the LNA further comprises a third transistor, and a second source inductor coupled to a source of the third transistor, wherein the second transistor is coupled between the output of the LNA and a drain of the third transistor, and wherein the method further comprises:
   receiving a second RF signal in a second frequency band;
   inputting the second RF signal to a gate of the third transistor; and
   magnetically coupling the second source inductor with the output inductor.
51. The method of clause 50, wherein:
   magnetically coupling the first source inductor with the output inductor comprises magnetically coupling the first source inductor with the output inductor with a first magnetic coupling coefficient between 0.05 and 0.3.
   magnetically coupling the second source inductor with the output inductor comprises magnetically coupling the second source inductor with the output inductor with a second magnetic coupling coefficient between 0.05 and 0.3.
52. The method of clause 50 or 51, further comprising:
   filtering the first RF signal using a first bandpass filter before inputting the first RF signal to the gate of the first transistor; and
   filtering the second RF signal using a second bandpass filter before inputting the second RF signal to the gate of the third transistor.
53. A low-noise amplifier (LNA), comprising:
   a first transistor;
   a first source inductor coupled to a source of the first transistor;
   a second transistor, wherein a source of the second transistor is coupled to a drain of the first transistor, a gate of the second transistor is coupled to a bias circuit, and a drain of the second transistor is coupled to an output of the LNA; and
   an output inductor coupled between a supply rail and the output of the LNA, wherein the output inductor is magnetically coupled with the first source inductor.
54. The LNA of clause 53, wherein the output inductor is arranged next to the first source inductor to achieve a magnetic coupling between the output inductor and the first source inductor.
55. The LNA of clause 53 or 54, wherein a magnetic coupling coefficient between the output inductor and the first source inductor is between 0.05 and 0.3.
56. The LNA of clauses 53 or 55, wherein the first source inductor partially overlaps the output inductor.
57. The LNA of any one of clause 53 or 55, further comprising:
   a third transistor, wherein a drain of the third transistor is coupled to the source of the second transistor; and
   a second source inductor coupled to a source of the third transistor, wherein the output inductor is magnetically coupled with the second source inductor.
58. The LNA of clause 57, wherein the output inductor is arranged next to the second source inductor to achieve a magnetic coupling between the output inductor and the second source inductor.
59. The LNA of clause 57 or 58, wherein a first magnetic coupling coefficient between the output inductor and the first source inductor is between 0.05 and 0.3, and a second magnetic coupling coefficient between the output inductor and the second source inductor is between 0.05 and 0.3.
60. The LNA of any one of clause 57 or 59, wherein the first source inductor partially overlaps the output inductor, and the second source inductor partially overlaps the output inductor.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a direct current (DC) ground or an alternating current (AC) ground, and thus the term “ground” covers both possibilities. An AC ground may be provided by a DC voltage.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system for wireless communications, comprising:
a low-noise amplifier (LNA), comprising:
a first transistor;
a first source inductor coupled to a source of the first transistor;
a second transistor, wherein a source of the second transistor is coupled to a drain of the first transistor, a gate of the second transistor is coupled to a bias circuit, and a drain of the second transistor is coupled to an output of the LNA; and
an output inductor coupled between a supply rail and the output of the LNA, wherein the output inductor is magnetically coupled with the first source inductor.

2. The system of claim 1, wherein the output inductor is arranged next to the first source inductor to achieve a magnetic coupling between the output inductor and the first source inductor.

3. The system of claim 1, wherein a magnetic coupling coefficient between the output inductor and the first source inductor is between 0.05 and 0.3.

4. The system of claim 1, wherein the first source inductor is placed next to the output inductor.

5. The system of claim 4, wherein at least one side of the first source inductor is adjacent to at least one side of the output inductor.

6. The system of claim 1, wherein the first source inductor and the output inductor have opposite polarities.

7. The system of claim 1, wherein the first source inductor and the output inductor are weakly magnetically coupled.

8. The system of claim 1, further comprising a filter coupled to a gate of the first transistor.

9. The system of claim 8, wherein the LNA further comprises a gate inductor coupled between the filter and the gate of the first transistor.

10. The system of claim 1, wherein the first source inductor partially overlaps the output inductor.

11. The system of claim 1, wherein the first source inductor is coupled between the source of the first transistor and a ground.

12. The system of claim 1, wherein the LNA further comprises:
a third transistor, wherein a drain of the third transistor is coupled to the source of the second transistor; and
a second source inductor coupled to a source of the third transistor, wherein the output inductor is magnetically coupled with the second source inductor.

13. The system of claim 12, wherein the output inductor is arranged next to the second source inductor to achieve a magnetic coupling between the output inductor and the second source inductor.

14. The system of claim 12, wherein a first magnetic coupling coefficient between the output inductor and the first source inductor is between 0.05 and 0.3, and a second magnetic coupling coefficient between the output inductor and the second source inductor is between 0.05 and 0.3.

15. The system of claim 12, wherein each of the first source inductor and the second source inductor is placed next to the output inductor.

16. The system of claim 15, wherein a first side of the output inductor is adjacent to the first source inductor, and a second side of the output inductor is adjacent to the second source inductor.

17. The system of claim 16, wherein the first side and the second side are opposing sides of the output inductor.

18. The system of claim 12, wherein the first source inductor and the output inductor have opposite polarities, and the second source inductor and the output inductor have opposite polarities.

19. The system of claim 12, further comprising:
a first filter coupled to a gate of the first transistor, wherein the first filter is configured to pass a first radio frequency (RF) signal in a first frequency band; and
a second filter coupled to a gate of the third transistor, wherein the second filter is configured to pass a second RF signal in a second frequency band different from the first frequency band.

20. The system of claim 19, wherein the LNA further comprises:
a first gate inductor coupled between the first filter and the gate of the first transistor; and
a second gate inductor coupled between the second filter and the gate of the third transistor.

21. The system of claim 12, further comprising one or more mixers coupled to the output of the LNA.

22. The system of claim 12, wherein the first source inductor partially overlaps the output inductor, and the second source inductor partially overlaps the output inductor.

23. The system of claim 12, wherein the first source inductor is coupled between the source of the first transistor and a ground, and the second source inductor is coupled between the source of the third transistor and the ground.

24. A system for wireless communications, comprising:
a radio frequency front-end (RFFE) circuit coupled to one or more antennas and comprising:
a low-noise amplifier (LNA), comprising:
a first transistor;
a first source inductor coupled to a source of the first transistor;
a second transistor, wherein a source of the second transistor is coupled to a drain of the first transistor, a gate of the second transistor is coupled to a bias circuit, and a drain of the second transistor is coupled to an output of the LNA; and
an output inductor coupled between a supply rail and the output of the LNA, wherein the output inductor is magnetically coupled with the first source inductor; and
a receiver coupled to the output of the LNA.

25. The system of claim 24, wherein the output inductor is arranged next to the first source inductor to achieve a magnetic coupling between the output inductor and the first source inductor.

26. The system of claim 24, wherein a magnetic coupling coefficient between the output inductor and the first source inductor is between 0.05 and 0.30.

27. The system of claim 24, wherein the first source inductor partially overlaps the output inductor.

28. A method for operating a wireless communications system including a low-noise amplifier (LNA), the LNA comprising a first transistor, a first source inductor coupled to a source of the first transistor, a second transistor coupled between an output of the LNA and a drain of the first transistor, and an output inductor coupled between a supply rail and the output of the LNA, the method comprising:
biasing a gate of the second transistor with a bias voltage;
receiving a first radio frequency (RF) signal in a first frequency band;
inputting the first RF signal to a gate of the first transistor; and
magnetically coupling the first source inductor with the output inductor.

29. The method of claim 28, wherein the output inductor is arranged next to the first source inductor to achieve a magnetic coupling between the output inductor and the first source inductor.

30. The method of claim 28, wherein magnetically coupling the first source inductor with the output inductor comprises magnetically coupling the first source inductor with the output inductor with a magnetic coupling coefficient between 0.05 and 0.3.
